(19) United States
(12) Patent Application Publication
(10) Pub. No.: US 2020/0127240 A1
(43) Pub. Date: Apr. 23, 2020

(54) OLED DEVICE MANUFACTURING METHOD AND OLED DEVICE

(71) Applicant: WUHAN CHINA STAR OPTOELECTRONICS SEMICONDUCTOR DISPLAY TECHNOLOGY CO., LTD., Wuhan, Hubei (CN)

(72) Inventor: Hongyang REN, Wuhan, Hubei (CN)

(21) Appl. No.: 16/334,750

(22) PCT Filed: Nov. 29, 2018
(86) PCT No.: PCT/CN2018/118138

§ 371 Date: Mar. 20, 2019

(30) Foreign Application Priority Data
Aug. 1, 2018 (CN) 201810863590.9

(51) Int. Cl. H01L 51/56; H01L 51/50; H01L 51/00; H01L 27/32

(52) U.S. Cl. CPC H01L 51/56; H01L 51/5092; H01L 51/5056; H01L 51/5206; H01L 51/0007; H01L 51/0011; H01L 27/3211; H01L 51/0005

(57) ABSTRACT

An organic light-emitting diode (OLED) device and a manufacturing method thereof are disclosed. The method includes steps of forming a first hole transmission unit on a hole injection layer and forming a first light emitting unit on the first hole transmission unit;

forming a second hole transmission unit on the hole injection layer and forming a second light emitting unit on the second hole transmission unit; and forming a third hole transmission unit on the hole injection layer and forming a third light emitting unit on the third hole transmission unit.

### FIELD OF INVENTION

The present disclosure relates to the technical field of displays, and specifically to an organic light emitting diode (OLED) device manufacturing method and an OLED device.

### BACKGROUND OF INVENTION

An organic light emitting diode (OLED) emits light used for display by an organic material layer without a backlight source, such that the OLED has features, such as fast response times, wider viewing angles, higher contrast, lighter devices, and low power consumption. An OLED technology is currently recognized as a flat panel display technology with the most potential.

Currently, a structure of the OLED consists of multi-layers with different functions, and a process for stacking material of various layers may generally be achieved by vacuum evaporation or inkjet printing technology. An OLED display of mobile phones with high-resolution can achieve resolution close to 600 pixels per inch (PPI) by a fine metal mask and evaporation technology, but the manufacturing process has very low utilization of OLED organic materials. In addition, large-sized OLED televisions are implemented by inkjet printing technology, in which the material utilization rate is much higher than that of an evaporation process, but it is limited by the size and accuracy of inkjet droplets, thereby the resolution is lower, generally around 230 PPI.

Therefore, it is necessary to find an OLED manufacturing art that may increase utilization of OLED materials and realize high resolution. In addition, the history of lithography technology development has been more than 200 years, the technical equipment is mature, and a complete process has been developed, such that materials used in lithography (such as photoresists or developers) are inexpensive to manufacture.

A method for manufacturing an OLED device with high resolution fabricated by combining the inkjet printing and lithography technologies is proposed in the present disclosure.

### SUMMARY OF INVENTION

Embodiments of the present disclosure provide an organic light emitting diode (OLED) device with high-resolution and a manufacturing method thereof based on a lithography technology and a special OLED pixel arrangement by an inkjet printing technology to achieve a stacking of organic material layers. The OLED device not only has higher resolution but also has a higher utilization of OLED materials. In addition, in a process of manufacturing the OLED device, the requirements for the process environment are also not as demanding strictly as vacuum evaporation requirements, and it is beneficial to improve product performance and reduce product cost.

An OLED device manufacturing method is provided in an embodiment of the present disclosure, which includes steps:
S1: forming a hole injection layer on an anode layer;
S2: forming a first hole transmission unit on the hole injection layer and forming a first light emitting unit on the first hole transmission unit;
S3: forming a second hole transmission unit on the hole injection layer and forming a second light emitting unit on the second hole transmission unit;
S4: forming a third hole transmission unit on the hole injection layer and forming a third light emitting unit on the third hole transmission unit; and
S5: forming the electron transmission layer on an organic light emitting layer; wherein the step S2 includes steps:
S21: coating a negative photoresist on the hole injection layer;
S22: baking the negative photoresist to harden the negative photoresist;
S23: disposing a lithographic mask corresponding to the first light emitting unit over the negative photoresist for exposure and development process, so as to remove an unexposed portion of the negative photoresist and to cause the negative photoresist to have a recessed region;
S24: forming the first hole transmission unit within the recessed region;
S25: forming the first light emitting unit on the first hole transmission unit; and
S26: stripping the remaining negative photoresist; and wherein the hole transmission layer is sprayed on the hole injection layer, the organic light emitting layer is sprayed on the hole transmission layer, by an inkjet printing technology.

In the OLED device manufacturing method of the present disclosure, a thickness of the negative photoresist is greater than a sum of thicknesses of the first hole transmission unit and the first light emitting unit.

In the OLED device manufacturing method of the present disclosure, in the step S25, an organic material used to form four first sub-pixels is sprayed on the first hole transmission unit to form the first light emitting unit.

In the OLED device manufacturing method of the present disclosure, the negative photoresist includes a photosensitive component, the photosensitive component includes a halogen solvent, a photo-acid generator compound, a monomer with at least one fluorine-containing group, and a copolymer including at least one monomer with an acid-decomposable ester-containing group.

In the OLED device manufacturing method of the present disclosure, further includes steps:
S6: spraying an electron injection layer on the electron transmission layer; and
S7: depositing a cathode layer on the electron injection layer through evaporation.

Another OLED device manufacturing method is provided in an embodiment of the present disclosure, which includes steps:
S1: forming a hole injection layer on an anode layer;
S2: forming a first hole transmission unit on the hole injection layer and forming a first light emitting unit on the first hole transmission unit;
S3: forming a second hole transmission unit on the hole injection layer and forming a second light emitting unit on the second hole transmission unit;
S4: forming a third hole transmission unit on the hole injection layer and forming a third light emitting unit on the third hole transmission unit; and
S5: forming the electron transmission layer on an organic light emitting layer.

In the OLED device manufacturing method of the present disclosure, the step S2 includes steps:
S21: coating a negative photoresist on the hole injection layer;
S22: baking the negative photoresist to harden the negative photoresist;
S23: disposing a lithographic mask corresponding to the first light emitting unit over the negative photoresist for exposure and development process, so as to remove an unexposed portion of the negative photoresist and to cause the negative photoresist to have a recessed region;
S24: forming the first hole transmission unit within the recessed region;
S25: forming the first light emitting unit on the first hole transmission unit; and
S26: stripping the remaining negative photoresist.

In the another OLED device manufacturing method of the present disclosure, a thickness of the negative photoresist is greater than a sum of thicknesses of the first hole transmission unit and the first light emitting unit.

In the another OLED device manufacturing method of the present disclosure, in the step S25, an organic material used to form four first sub-pixels is sprayed on the first hole transmission unit to form the first light emitting unit.

In the another OLED device manufacturing method of the present disclosure, the negative photoresist includes a photosensitive component, the photosensitive component includes a halogen solvent, a photo-acid generator compound, a monomer with at least one fluorine-containing group, and a copolymer including at least one monomer with an acid-decomposable ester-containing group.

In the another OLED device manufacturing method of the present disclosure, the hole transmission layer is sprayed on the hole injection layer, the organic light emitting layer is sprayed on the hole transmission layer, by an inkjet printing technology.

In the another OLED device manufacturing method of the present disclosure, further includes steps:
S6: spraying an electron injection layer on the electron transmission layer; and
S7: depositing a cathode layer on the electron injection layer through evaporation.

The present disclosure also relates to an OLED device, which is manufactured by the above method and includes:
an anode layer;
a hole injection layer formed on the anode layer;
a hole transmission layer formed on the hole injection layer;
an organic light emitting layer formed on the hole transmission layer; and
an electron transmission layer formed on the organic light emitting layer;
wherein the organic light emitting layer includes a plurality of first light emitting units, a plurality of second light emitting units, and a plurality of third light emitting units; colors of light emitted from the first light emitting units, the second light emitting units, and the third light emitting units are different; the hole transmission layer includes a plurality of first hole transmission units corresponding to the first light emitting units, a plurality of second hole transmission units corresponding to the second light emitting units, and a plurality of third hole transmission units corresponding to the third light emitting units; and thicknesses of the first hole transmission units, the second hole transmission units, and the third hole transmission units are different.

In the OLED device of the present disclosure, each of the first light emitting units emits red light, each of the second light emitting units emits green light, and each of the third light emitting units emits blue light; and the thickness of each of third hole transmission units is less than the thickness of each of second hole transmission units, and the thickness of each of second hole transmission units is less than the thickness of each of first hole transmission units.

In the OLED device of the present disclosure, the thickness of each of first hole transmission units is 200±2 nm, the thickness of each of second hole transmission units is 160±2 nm, and the thickness of each of third hole transmission units is 120±2 nm.

In the OLED device of the present disclosure, each of the first light emitting units includes four first sub-pixels, each of the second light emitting units includes four second sub-pixels, and each of the third light emitting units includes four third sub-pixels.

Compared with an OLED device in the prior art, in the method of manufacturing the OLED device of the present disclosure, by combining the lithography technology and the inkjet printing technology, to achieve high utilization of OLED materials, high resolution of the OLED device, increasing performance of the product, and reducing the cost of the product, thereby solving a technical problem of low material utilization and low resolution of the OLED device in the prior art.

### BRIEF DESCRIPTION OF DRAWINGS

In order to more clearly illustrate technical solutions in the embodiments of the present disclosure or the prior art, drawings used in the embodiments will be briefly described below. The drawings in the following description are merely a part of the embodiments of the present disclosure, and other drawings may be obtained from those skilled in the art without any creative work.

FIG. 1 is a flowchart of an organic light emitting diode (OLED) device manufacturing method according to an embodiment of the present disclosure.

FIG. 2 is a flowchart in a text form of a step S2 of the OLED device manufacturing method according to the embodiment of the present disclosure.

FIG. 3 is a flowchart in a drawing form of the step S2 of the OLED device manufacturing method according to the embodiment of the present disclosure.

FIG. 4 is a schematic structural diagram of an OLED device according to an embodiment of the present disclosure.

FIG. 5 is a schematic structural diagram of a pixel arrangement of the OLED device according to the embodiment of the present disclosure.

### DETAILED DESCRIPTION OF PREFERRED EMBODIMENTS

Please refer to drawings, the same symbols are used to represent the same components. The following description is based on specific embodiments of the present disclosure as illustrated and should not be considered as limiting to other specific embodiments that are not specifically described herein.

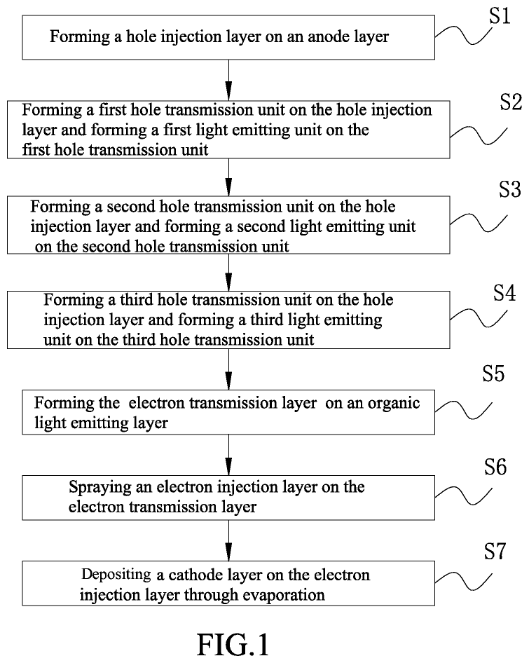

Please refer to FIGS. 1 and 3. An organic light emitting diode (OLED) device manufacturing method of the present disclosure includes steps:
S1: forming a hole injection layer 12 on an anode layer (not shown in figure);
S2: forming a first hole transmission unit 131 on the hole injection layer 12 and forming a first light emitting unit 141 on the first hole transmission unit 131;
S3: forming a second hole transmission unit 132 on the hole injection layer 12 and forming a second light emitting unit 142 on the second hole transmission unit 132;
S4: forming a third hole transmission unit 133 on the hole injection layer 12 and forming a third light emitting unit 143 on the third hole transmission unit 133; and
S5: forming an electron transmission layer 15 on an organic light emitting layer.

In the present embodiment, the steps S2, S3, and S4 are performed without a particular order, and one of the three steps can be followed by the others. Three colors, R, G, B (such as the first light emitting unit 141, the second light emitting unit 142, and the third light emitting unit 143) are taken as an example described in the present embodiment, but that is not limited as described here. The organic light emitting layer includes the first light emitting unit 141, the second light emitting unit 142, and the third light emitting unit 143, which emit light in different colors. A hole transmission layer includes the first hole transmission unit 131 corresponding to the first light emitting unit 141, the second hole transmission unit 132 corresponding to the second light emitting unit 142, and the third hole transmission unit 133 corresponding to the third light emitting unit 143.

In the present embodiment, an object of adjusting thicknesses of the first hole transmission unit 131, the second hole transmission unit 132, and the third light emitting unit 143 is achieved by spraying the first hole transmission unit 131, the second hole transmission unit 132, and the third light emitting unit 143 corresponding to the three light emitting units, respectively. Such that, the micro-cavity effect of different colors is adjusted to achieve a purpose of balancing colors.

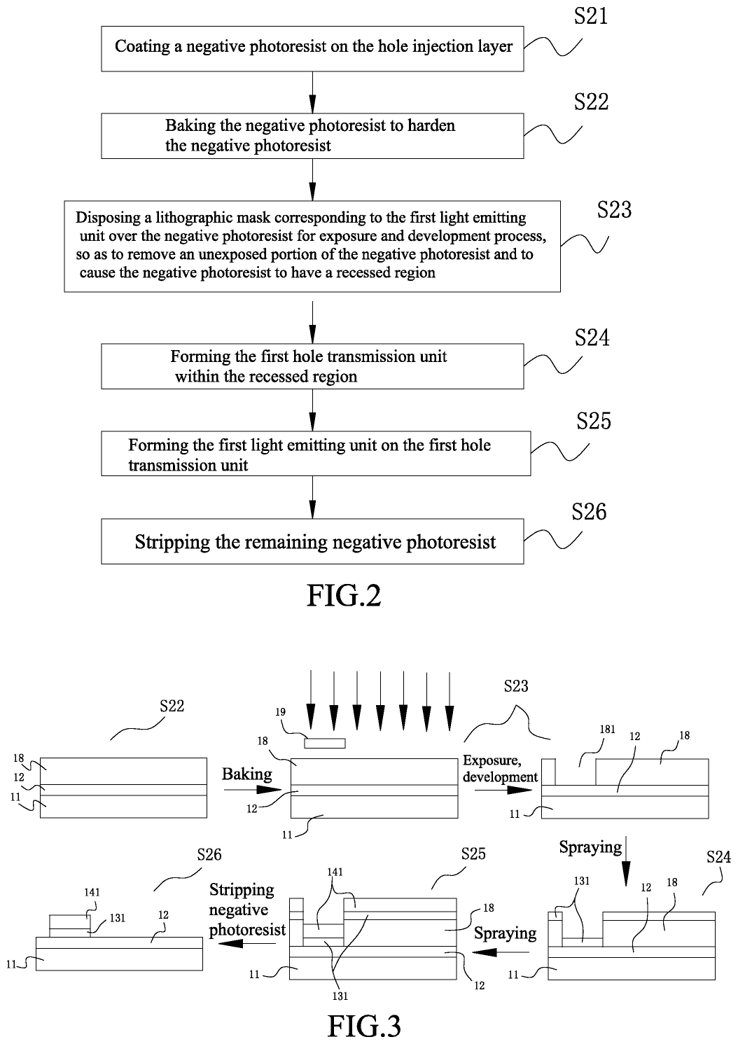

Specifically, please refer to FIGS. 2 and 3, in the OLED device manufacturing method of the present disclosure, the step S2 includes steps:
S21: coating a negative photoresist 18 on the hole injection layer 12;
S22: baking the negative photoresist 18 to harden the negative photoresist 18;
S23: disposing a lithographic mask 19 corresponding to the first light emitting unit 141 over the negative photoresist 18 for an exposure and development process, so as to remove an unexposed portion of the negative photoresist 18 and to cause the negative photoresist 18 to have a recessed region 181;
S24: forming the first hole transmission unit 131 within the recessed region 181;
S25: forming the first light emitting unit 141 on the first hole transmission unit 131; and
S26: stripping the remaining negative photoresist 18.

In the present embodiment, the negative photoresist 18 is a negative photoresist for typesetting organic materials, which is described in patent publication No. US 20140127625 A1.

The negative photoresist 18, and a developer and stripper associated with the negative photoresist 18 are compatible with organic materials and do not destroy the properties of the organic materials.

The negative photoresist 18 includes a photosensitive component, the photosensitive component includes a halogen solvent, a photo-acid generator compound, a monomer with at least one fluorine-containing group, and a copolymer including at least one monomer with an acid-decomposable ester-containing group.

In the step S2, the first hole transmission unit 131 and the first light emitting unit 141 are sprayed by an inkjet printing technology. In addition, liquid medium related to the inkjet printing technology does not physically or chemically react with the negative photoresist. Because of blocking via the negative photoresist 18, ink droplets of the organic material can be directly sprayed on an active area (AA) of a substrate of the OLED device by the inkjet printing technology, such that resolution is determined by the above lithography process, which can achieve the resolution of 600 pixels per inch (PPI) without being affected from inkjet precision in the inkjet printing technology.

Specific processes of the steps S3 and S4 are identical or similar to the step S2. The negative photoresist 18 is stripped by the stripper, which only dissolves the photoresist, and a layer of the organic material in a development zone will be remained.

In the OLED device manufacturing method of the present disclosure, thickness of the negative photoresist 18 is greater than a sum of the thickness of the first hole transmission unit 131 and the first light emitting unit 141, such an arrangement facilitates stripping of the subsequent negative photoresist 18. Similarly, the thickness of the negative photoresist 18 is greater than a sum of the thickness of the second hole transmission unit 132 and the second light emitting unit 142, and the thickness of the negative photoresist 18 is greater than a sum of the thickness of the third hole transmission unit 133 and the second light emitting unit 143.

The thickness of each of first hole transmission units is 200±2 nm, the thickness of each of second hole transmission units is 160±2 nm, and the thickness of each of third hole transmission units is 120±2 nm.

In the OLED device manufacturing method of the present disclosure, in the step S25, an organic material used to form four first sub-pixels 14a is sprayed on the first hole transmission unit 131 to form the first light emitting unit 141.

Similarly, the second light emitting unit 142 and the third light emitting unit 143 all have four sub-pixels with the same color.

Please refer to FIG. 5, an unexposed portion of a lithographic mask 19 corresponding to the first light emitting unit 141 is a first unexposed portion 21, the unexposed portion of the lithographic mask 19 corresponding to the second light emitting unit 142 is a second unexposed portion 22, and the unexposed portion of the lithographic mask 19 corresponding to the first light emitting unit 141 is a third unexposed portion 23, wherein the resolution of 600 PPI may be implemented through the lithographic mask 19.

A red organic material is correspondingly sprayed on the four sub-pixels of the first unexposed portion 21, a green organic material is correspondingly sprayed on the four sub-pixels of the second unexposed portion 22, and the blue organic material is correspondingly sprayed on the four sub-pixels of the third unexposed portion 23, thereby increasing the resolution of the lithographic mask up to 4 times, that is, 2400 PPI.

In the OLED device manufacturing method of the present disclosure, the OLED device manufacturing method further includes steps:
S6: spraying an electron injection layer 16 on the electron transmission layer 15; and
S7: depositing a cathode layer 17 on the electron injection layer 16 through evaporation.

In the OLED device manufacturing method of the present disclosure, the lithographic technology is combined with the inkjet printing technology to realize a fabrication of the OLED device with high resolution, effectively improving utilization of the organic material of the OLED, and reducing cost, under a condition without a fine lithography mask required, thereby the condition of manufacturing the OLED device may be simplified, and requirements of a specification of the device may be reduced.

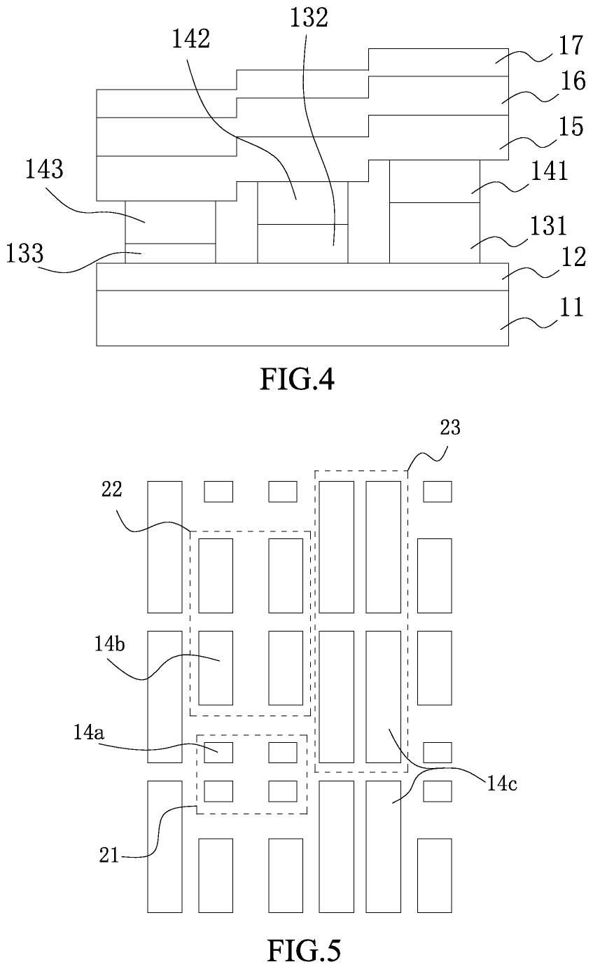

Please refer to FIG. 4, which is a schematic structural diagram of an OLED device according to an embodiment of the present disclosure. The OLED device according to an embodiment of the present disclosure is manufactured by the OLED device manufacturing method. The OLED device of the present disclosure includes a substrate (not shown in figure), an anode layer 11, a hole injection layer 12, a hole transmission layer, an organic light emitting layer, an electron transmission layer 15, an electron injection layer 16, and a cathode layer 17.

Specifically, the anode layer is disposed on the substrate, the hole injection layer 12 is formed on the anode layer 11, the hole transmission layer is formed on the hole injection layer 12, the organic light emitting layer is formed on the hole transmission layer, and the electron transmission layer 15 is formed on the organic light emitting layer.

The organic light emitting layer includes a plurality of first light emitting units 141, a plurality of second light emitting units 142, and a plurality of third light emitting units 143. Colors of light emitted from the first light emitting units 141, the second light emitting units 142, and the third light emitting units 143 are different. The hole transmission layer includes a plurality of first hole transmission units 131 corresponding to the first light emitting units 141, a plurality of second hole transmission units 132 corresponding to the second light emitting units 142, and a plurality of third hole transmission units 133 corresponding to the third light emitting units 143.

The thickness of the first hole transmission units 131, the second hole transmission units 132, and the third hole transmission units 133 are different.

In the present embodiment, an object of balancing colors is achieved by adjusting thickness of the first hole transmission unit 131, the second hole transmission unit 132, and the third light emitting unit 143 to adjust the micro-cavity effect of different colors.

Specifically, in the OLED device of the present embodiment, each of the first light emitting units 141 emits red light, each of the second light emitting units 142 emits green light, and each of the third light emitting units 143 emits blue light; and the thickness of each of the third hole transmission units 133 is less than the thickness of each of the second hole transmission units 132, and the thickness of each of the second hole transmission units 132 is less than the thickness of each of the first hole transmission units 131.

When the thickness of each of the first hole transmission units 131 is set maximally and the thickness of each of the third hole transmission units 133 is set minimally, the colors of red, green, and blue are balanced.

Further, in the OLED device of the present embodiment, the thickness of each of the first hole transmission units is 200±2 nm, the thickness of each of the second hole transmission units is 160±2 nm, and the thickness of each of the third hole transmission units is 120±2 nm.

Please refer to FIG. 5, which is a schematic structural diagram of a pixel arrangement of the OLED device according to the embodiment of the present disclosure. In the OLED device of the present embodiment, each of the first light emitting units 141 includes four first sub-pixels 14a, each of the second light emitting units 142 includes four second sub-pixels 14b, and each of the third light emitting units 143 includes four third sub-pixels 14c.

Each of the first sub-pixels 14a is a sub-pixel emitting red light, each of the second sub-pixels 14b is a sub-pixel emitting green light, and each of the third sub-pixels 14c is a sub-pixel emitting blue light. The four first sub-pixels 14a, the four second sub-pixels 14b, and the four third sub-pixels 14c are arranged in an array manner.

In the present embodiment, the OLED device is manufactured by combining the lithography technology and the inkjet printing technology. In the process of manufacturing the OLED device of the present embodiment, because of blocking via the negative photoresist 18, ink droplets of the organic material can be directly sprayed on an active area (AA) of the substrate of the OLED device by the inkjet printing technology, such that resolution is determined by the above lithography process without being affected from inkjet precision in the inkjet printing technology. In addition, the resolution of 600 PPI can be achieved in the lithography process.

In addition, four in one configuration is adopted in the OLED pixel arrangement, and improves the resolution to 2400 PPI, namely, four the same sub-pixels are designed as a sub-pixel unit (light emitting unit). In the process, the corresponding organic materials are sprayed on the four sub-pixels over the hole transmission layer, thereby increasing the overall resolution to four times of the resolution of the lithographic mask 19, that is, 2400 PPI.

Further, the third light emitting units 143 are disposed in odd columns. The second light emitting units 142 and the first light emitting units 141 are alternately arranged in even columns. A sum of lengths of one of the first sub-pixels 14a and one of the second sub-pixels 14b is equal to a length of one of the third sub-pixels 14c.

In addition, an area of each of the first sub-pixels 14a is less than an area of each of the third sub-pixels 14c, the area of each of the first sub-pixels 14a is greater than an area of each of the second sub-pixels 14b, such an arrangement may improve the uniformity of pixel illumination.

Compared with an OLED device in the prior art, the method of manufacturing the OLED device of the present disclosure, by combining the lithography technology and the inkjet printing technology, achieves high utilization of OLED materials, achieves high resolution of the OLED device, increases performance of the product, and reduces the cost of the product, thereby solving a technical problem of low material utilization and low resolution of the OLED device in the prior art.

In the above, various changes and modifications can be made by those skilled in the art in accordance with the technical solutions and technical concept of the present disclosure, and all such changes and modifications shall fall into the scope of protection of the claims appended to the disclosure.

What is claimed is:

1. An organic light emitting diode (OLED) device manufacturing method, comprising steps:
S1: forming a hole injection layer on an anode layer;
S2: forming a first hole transmission unit on the hole injection layer and forming a first light emitting unit on the first hole transmission unit;
S3: forming a second hole transmission unit on the hole injection layer and forming a second light emitting unit on the second hole transmission unit;
S4: forming a third hole transmission unit on the hole injection layer and forming a third light emitting unit on the third hole transmission unit; and
S5: forming an electron transmission layer on an organic light emitting layer; wherein the step S2 comprises steps:
S21: coating a negative photoresist on the hole injection layer;
S22: baking the negative photoresist to harden the negative photoresist;
S23: disposing a lithographic mask corresponding to the first light emitting unit over the negative photoresist for an exposure and development process, so as to remove an unexposed portion of the negative photoresist and to cause the negative photoresist to have a recessed region;
S24: forming the first hole transmission unit within the recessed region;
S25: forming the first light emitting unit on the first hole transmission unit; and
S26: stripping the remaining negative photoresist; and
wherein a hole transmission layer is sprayed on the hole injection layer, the organic light emitting layer is sprayed on the hole transmission layer, by an inkjet printing technology.

2. The OLED device manufacturing method as claimed in claim 1, wherein thickness of the negative photoresist is greater than a sum of thickness of the first hole transmission unit and the first light emitting unit.

3. The OLED device manufacturing method as claimed in claim 1, wherein in the step S25, an organic material used to form four first sub-pixels is sprayed on the first hole transmission unit to form the first light emitting unit.

4. The OLED device manufacturing method as claimed in claim 1, wherein the negative photoresist comprises a photosensitive component, the photosensitive component comprises a halogen solvent, a photo-acid generator compound, a monomer with at least one fluorine-containing group, and a copolymer comprising at least one monomer with an acid-decomposable ester-containing group.

5. The OLED device manufacturing method as claimed in claim 1, further comprises steps:
S6: spraying an electron injection layer on the electron transmission layer; and
S7: depositing a cathode layer on the electron injection layer through evaporation.

6. An organic light emitting diode (OLED) device manufacturing method, comprising steps:
S1: forming a hole injection layer on an anode layer;
S2: forming a first hole transmission unit on the hole injection layer and forming a first light emitting unit on the first hole transmission unit;
S3: forming a second hole transmission unit on the hole injection layer and forming a second light emitting unit on the second hole transmission unit;
S4: forming a third hole transmission unit on the hole injection layer and forming a third light emitting unit on the third hole transmission unit; and
S5: forming an electron transmission layer on an organic light emitting layer.

7. The OLED device manufacturing method as claimed in claim 6, wherein the step S2 comprises steps:
S21: coating a negative photoresist on the hole injection layer;
S22: baking the negative photoresist to harden the negative photoresist;
S23: disposing a lithographic mask corresponding to the first light emitting unit over the negative photoresist for an exposure and development process, so as to remove an unexposed portion of the negative photoresist and to cause the negative photoresist to have a recessed region;
S24: forming the first hole transmission unit within the recessed region;
S25: forming the first light emitting unit on the first hole transmission unit; and
S26: stripping the remaining negative photoresist.

8. The OLED device manufacturing method as claimed in claim 7, wherein thickness of the negative photoresist is greater than a sum of thickness of the first hole transmission unit and the first light emitting unit.

9. The OLED device manufacturing method as claimed in claim 7, wherein in the step S25, an organic material used to form four first sub-pixels is sprayed on the first hole transmission unit to form the first light emitting unit.

10. The OLED device manufacturing method as claimed in claim 7, wherein the negative photoresist comprises a photosensitive component, the photosensitive component comprises a halogen solvent, a photo-acid generator compound, a monomer with at least one fluorine-containing group, and a copolymer comprising at least one monomer with an acid-decomposable ester-containing group.

11. The OLED device manufacturing method as claimed in claim 6, wherein a hole transmission layer is sprayed on the hole injection layer, the organic light emitting layer is sprayed on the hole transmission layer, by an inkjet printing technology.

12. An organic light emitting diode (OLED) device, comprising:
an anode layer;
a hole injection layer formed on the anode layer;
a hole transmission layer formed on the hole injection layer;
an organic light emitting layer formed on the hole transmission layer; and
an electron transmission layer formed on the organic light emitting layer;
wherein the organic light emitting layer comprises a plurality of first light emitting units, a plurality of second light emitting units, and a plurality of third light emitting units; colors of light emitted from the first light emitting units, the second light emitting units, and the third light emitting units are different; the hole transmission layer comprises a plurality of first hole transmission units corresponding to the first light emitting units, a plurality of second hole transmission units corresponding to the second light emitting units, and a plurality of third hole transmission units corresponding to the third light emitting units; and
thickness of the first hole transmission units, the second hole transmission units, and the third hole transmission units are different.

13. The OLED device as claimed in claim 12, wherein each of the first light emitting units emits red light, each of the second light emitting units emits green light, and each of the third light emitting units emits blue light; and the thickness of each of the third hole transmission units is less than the thickness of each of second hole transmission units, and the thickness of each of the second hole transmission units is less than the thickness of each of the first hole transmission units.

14. The OLED device as claimed in claim 13, wherein the thickness of each of the first hole transmission units is 200±2 nm, the thickness of each of the second hole transmission units is 160±2 nm, and the thickness of each of the third hole transmission units is 120±2 nm.

15. The OLED device as claimed in claim 12, wherein each of the first light emitting units comprises four first sub-pixels, each of the second light emitting units comprises four second sub-pixels, and each of the third light emitting units comprises four third sub-pixels.
